(19) United States
(12) Patent Application Publication
(10) Pub. No.: US 2026/0068036 A1
(43) Pub. Date: Mar. 5, 2026

(54) PLANAR SOLDER JOINT WITH DIAGONAL TRACE FOR DETERMINING SOLDER DIMENSION TO PREVENT ELECTROMIGRATION

(71) Applicant: International Business Machines Corporation, Armonk, NY (US)

(72) Inventor: Prabjit SINGH, Poughkeepsie, NY (US)

(21) Appl. No.: 18/824,875

(22) Filed: Sep. 4, 2024

(51) Int. Cl. H05K 1/02; H05K 3/18; H05K 3/34

(52) U.S. Cl. CPC H05K 1/0265; H05K 3/188; H05K 3/346; H05K 2201/032; H05K 2201/0769; H05K 2201/09227; H05K 2201/09272; H05K 2201/09281; H05K 2201/09827

(57) ABSTRACT

A substrate may comprise a first conductive trace over a substrate and a second conductive trace over the substrate. The first conductive trace and the second conductive trace may be separated by a length. The substrate may include a solder joint bridging the first conductive trace and the second conductive trace and a third conductive trace diagonally bisecting the solder joint to form a first solder joint portion and a second solder joint portion. A first length of the first solder joint portion may taper to zero from the length. A second length of the second solder joint portion may taper to zero from the length.

### BACKGROUND

The present invention relates to solder joints of printed circuit boards, and for example, relates to mitigating electromigration in solder joints. A printed circuit board may include multiple components, such as integrated circuits, conductive traces, and wiring. In some situations, some of the components may be electrically connected using solder joints. The solder joints may be subjected to electromigration as a result of electron current flowing through the solder joints.

### SUMMARY

In some implementations, a method includes forming a first conductive trace over a substrate; forming a second conductive trace over the substrate, wherein the first conductive trace and the second conductive trace are separated by a length, and wherein a first width of the first conductive trace is equal to a second width of the second conductive trace; forming a third conductive trace between the first conductive trace and the second conductive trace, wherein the third conductive trace is provided diagonally between the first conductive trace and the second conductive trace; and forming a solder joint between the first conductive trace and the second conductive trace, wherein the third conductive trace bisects the solder joint diagonally to form a first solder joint portion and a second solder joint portion.

In some implementations, a substrate comprising: a first conductive trace over a substrate; a second conductive trace over the substrate, wherein the first conductive trace and the second conductive trace are separated by a length; a solder joint bridging the first conductive trace and the second conductive trace; and a third conductive trace diagonally bisecting the solder joint to form a first solder joint portion and a second solder joint portion, wherein a first length of the first solder joint portion tapers to zero from the length, and wherein a second length of the second solder joint portion tapers to zero from the length.

In some implementations, a substrate comprising: a first conductive trace over a substrate; a second conductive trace over the substrate; a planar, thin, rectangular solder joint bridging a first conductive trace and a second conductive trace that are of a same thickness and width; and a third conductive trace that diagonally bisects the solder joint to provide two solder joint portions, each solder joint point having a length tapering to zero such that each solder joint portion ensures uniform current density.

### BRIEF DESCRIPTION OF THE DRAWINGS

FIGS. 1A and 1B are diagrams of a top view of an example structure described herein.

FIG. 2 is a diagram of a cross sectional view of an example structure described herein.

FIG. 3 is a diagram of an electromigration perceived from a top view of an example structure described herein.

FIG. 4 is a flowchart of an example process associated with fabricating an example structure described herein.

### DETAILED DESCRIPTION

The following detailed description of example implementations refers to the accompanying drawings. The same reference numbers in different drawings may identify the same or similar elements.

Low-melting temperature tin-bismuth solder joints (e.g., eutectic tin-bismuth solder joint), with a melting point of 138° C., are widely used in the area of semiconductor packaging for multiple reasons. For example, tin-bismuth solder joints provide low assembly warpage at low soldering temperatures.

Additionally, tin-bismuth solder joints allow the use of lower-temperature resistant components and materials. Lower-temperature resistant components and materials cannot tolerate high assembly temperatures. Additionally, electronic assembly processes using tin-bismuth solder consume less energy during soldering.

In some situations, a tin-bismuth solder joint may be subjected to an electron current. As explained herein, the electron current may cause electromigration of atoms included in the solder joint. Typically, an electron current at high application temperatures causes bismuth atoms (of the tin-bismuth solder) to migrate and collect at a downstream interface of the tin-bismuth solder joint (e.g., an interface contacting an anode). The migration (e.g., electromigration) and collection of the bismuth atoms, at the downstream interface, may result in a thick brittle bismuth layer that makes the solder joint prone to physical damage, such as thermal and mechanical shock cracking. Additionally, the migration and collection of the bismuth atoms may affect other physical characteristics of the solder joint. For example, the migration and collection of the bismuth atoms may increase a resistance (e.g., electrical resistance) of the solder joint. The increase in resistance and/or the thermal and mechanical shock cracking may affect an operation of components associated with the solder joint, including components electrically coupled using the solder joint.

Currently, low-melting temperature tin-bismuth solder joint (e.g., eutectic tin-bismuth solder) is very prone to the electromigration discussed above. The solder joint is typically a near spherical component (three dimensional component). In this regard, a technical problem herein is to determine a critical height of the solder joint that prevents (or at least significantly reduces) the electromigration of bismuth atoms. A solder joint with height less than the critical height would suffer no (or at least significantly reduced) electromigration. One way to study an effect of the height of the solder joint with respect to the electromigration may be to take a cross section of the solder joint and monitor the electromigration using the cross section, as the height of the solder joint is decreased. However, taking a cross section of the solder joint damages the solder joint to the point that prevents monitoring the electromigration. Another way to study an effect of the height of the solder joint with respect to the electromigration may be to fabricate a planar solder joint (e.g., a non-spherical solder joint) and monitoring the electromigration as a length of the planar solder joint is decreased. For example, a length of the solder joint may be decreased to reduce the electromigration of the bismuth atoms. However, current state of the art does not enable a fabrication of a planar solder joint with a sufficiently decreased length to prevent (or at significantly reduce) the electromigration. A planar solder joint may refer to a solder joint with a thickness that is less than a particular threshold (e.g., 30 μm or less). For at least the foregoing reasons, a need exists for a structure that enables monitoring a decrease in the length of the planar solder joint to the point of preventing or significantly reducing electromigration of bismuth in tin-bismuth solder joints. For example, a need exists to determine (e.g., by visual observation) a length of the solder joint, that may be fabricated, below which electromigration will not occur, due to a phenomenon called electromigration back stress. Additionally, a technique is needed to evaluate the electromigration propensity of tin-bismuth alloys, or other low melting alloys, of various compositions to come up with an alloy with low electromigration propensity.

Implementations described herein are directed to a structure that may be used to monitor (e.g., visually) electromigration of bismuth atoms as a length of a planar solder joint is reduced. As the length of the planar solder joint is reduced, electromigration of bismuth atoms in tin-bismuth solder joints may be reduced. A thickness of the structure may be 0.030 mm (30 μm). The structure may include a planar solder joint that bridges (or connects) copper traces. The copper traces may have width of 2 mm.

The planar solder joint may have a rectangular shape (or a square shape). The planar solder joint may be bisected by a diagonal trace. For example, the diagonal trace may separate the planar solder joint into two identical triangles (or substantially identical triangles). The diagonal trace may include an electromigration resistant metal. Alternatively, the diagonal trace may be a very narrow copper trace. For example, the diagonal trace may include copper and may have a reduced width (e.g., less than a width threshold). As explained herein, the diagonal trace may gradually reduce a length of the planar solder joint. As a result of gradually reducing the length of the planar solder joint, the electromigration may gradually reduce to a point of no electromigration (e.g., reduced to zero). A length of the planar solder joint corresponding to the point of no electromigration may be identified as the length below which electromigration does not occur (also refer to as “critical length” or “particular solder length”). A material and/or a thickness of the diagonal trace may be chosen such that the diagonal trace may change a length of the solder joint while maintaining an electron current uniformly flowing through solder joint.

By changing the length of the solder joint, the diagonal trace may be used to identify a dimension of a solder joint under which bismuth atoms will not migrate toward an anode of the structure. The novelty of the structure is that the structure allows uniform current density across the identical triangles (or substantially identical triangles). Accordingly, the structure can be used to visually observe the progress of electromigration as a function of the length of the solder joint. Visual observation of the structure stressed at high current, and temperature shows a length below which electromigration cannot occur. The length of the planar solder joint may correspond to a height of the solder joint (e.g., spherical solder joint). In some situations, the structure may be included on a printed circuit board.

In some examples, an electron current flowing through the copper traces may have uniform current density. The diagonal trace may distort the current density uniformity. This distortion may be reduced by reducing a thickness of the diagonal trace or by using a trace of a less conductive material. Implementations described herein are directed to a method of fabricating the structure.

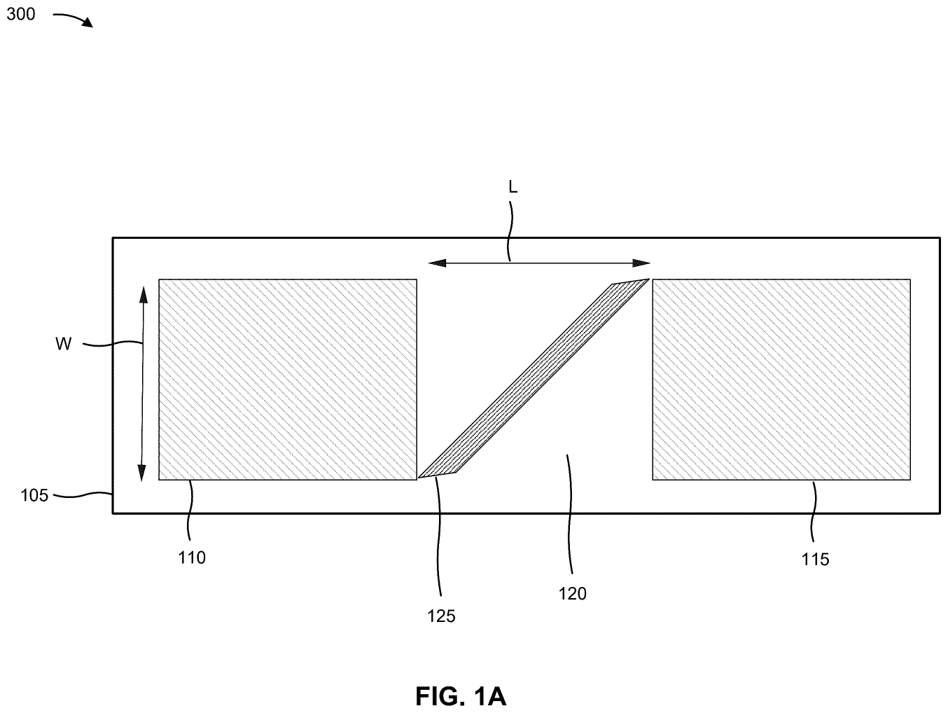

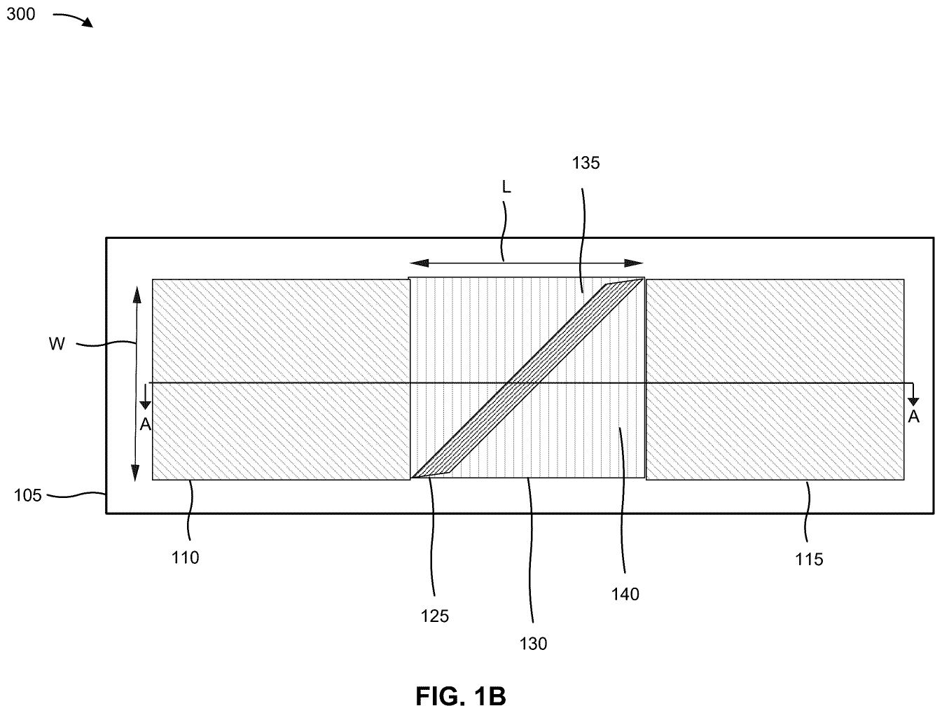

FIGS. 1A and 1B are diagrams of a top view of an example structure 100 described herein. As shown in FIG. 1A, structure 100 may include a printed circuit board (PCB) 105, a first conductive trace 110, and a second conductive trace 115. First conductive trace 110 and second conductive trace 115 may be formed on PCB 105. In some situations, PCB 105 may include a test PCB.

First conductive trace 110 may include copper. In other words, first conductive trace 110 may include a copper trace. First conductive trace 110 may have a width W. In some examples, width W may be 2 mm. In some examples, first conductive trace 110 may be a 1-oz copper trace. In this regard, a thickness of first conductive trace 110 may be 0.030 mm. First conductive trace 110 may be formed on PCB 105 by being printed on PCB 105. In some situations, first conductive trace 110 may be formed by electroplating on PCB 105.

Second conductive trace 115 may include copper. In other words, second conductive trace 115 may include a copper trace. Second conductive trace 115 may have a width W. In some examples, width W may be 2 mm. In some examples, second conductive trace 115 may be a 1-oz copper trace. In this regard, a thickness of second conductive trace 115 may be 0.030 mm. Second conductive trace 115 may be formed on PCB 105 by being printed on PCB 105. In some situations, second conductive trace 115 may be formed by electroplating on PCB 105. In some examples, first conductive trace 110 and second conductive trace 115 may be formed simultaneously.

As shown in FIG. 1A, first conductive trace 110 and second conductive trace 115 may be separated by a gap 120 with a length L. In some examples, length L may be 0.1 mm. As shown in FIG. 1A, structure 100 may include a third conductive trace 125 provided diagonally in gap 120. As shown in FIG. 1A, third conductive trace 125 may bisect gap 120. Third conductive trace 125 may include an electromigration resistant metal. For example, third conductive trace 125 may include nickel titanium alloy. For example, third conductive trace 125 may include nichrome. Third conductive trace 125 may distort a current density uniformity of an electron current that is applied to a solder joint (e.g., provided in gap 120 discussed herein). This distortion may be reduced by reducing a thickness of third conductive trace 125 or by using a trace of a less conductive material (e.g., less conductive than copper). In other words, an electrical conductivity of first conductive trace 110 or second conductive trace 115 may exceed an electrical conductivity of third conductive trace 125. In some implementations, third conductive trace 125 may include copper.

As shown in FIG. 1B, structure 100 may further include a solder joint 130. As shown in FIG. 1B, solder joint 130 may be bisected by third conductive trace 125 to form a first solder joint portion 135 and a second solder joint portion 140. As shown in FIG. 1B, solder joint 130 may have a form of a rectangle (or a square). In this regard, first solder joint portion 135 and second solder joint portion 140 may have a form of a triangle. In this example, first solder joint portion 135 and second solder joint portion 140 may be triangles of same dimensions (or similar dimensions).

In some situations, solder joint 130 may be formed by depositing solder paste in gap 120. For example, gap 120 may be painted (or filled) with solder paste and covered with a covering material. The covering material may include copper foil. A thickness of the copper foil may be approximately 0.1 mm. The solder paste may be reflowed and cooled. The term “reflow” may be used to refer to melting the solder paste by heating above a melting point of the solder. In some implementations, the solder paste may be deposited after third conductive trace 125 has been provided diagonally in gap 120. The copper foil may be removed (e.g., peeled off). In some situations, the solder, first conductive trace 110, and second conductive trace 115 may be ground and polished to obtain a surface suitable for metallographic examination of the microstructure of the first solder joint portion 135 and the second solder joint portion 140. A specimen can be ground using abrasive paper to remove some material. When enough extraneous material has been ground away, the specimen surface can be polished.

In some implementations, the solder paste may be deposited before third conductive trace 125 has been provided diagonally in gap 120. For example, gap 120 may be painted (or filled) with solder paste and covered with a covering material. The covering material may include copper foil. A thickness of the copper foil may be 0.1 mm. The solder (e.g., solder paste) may be reflowed and cooled. The copper foil may be removed (e.g., peeled off). In some situations, the solder, first conductive trace 110, and second conductive trace 115 may be ground and polished to obtain a surface suitable for metallographic examination of the microstructure of the solder joint.

After the grounding and the polishing, third conductive trace 125 may be placed diagonally in gap 120. Third conductive trace 125 may be a metal wire with a diameter of 0.1 mm. A glass slide placed on top of third conductive trace 125 with an object on the glass. A weight of the object may satisfy a weight threshold. An assembly (formed by third conductive trace 125 and solder joint 130) may be heated to about 100° C. so that third conductive trace 125 may penetrate solder joint 130, separating into two identical triangles (e.g., first solder joint portion 135 and second solder joint portion 140).

As indicated above, FIGS. 1A and 1B are provided as examples. Other examples may differ from what is described with regard to FIGS. 1A and 1B. The number and arrangement of devices shown in FIGS. 1A and 1B are provided as an example. There may be additional components (e.g., a large number of components), fewer components, different components, or differently arranged components than those shown in FIGS. 1A and 1B. Furthermore, two or more components shown in FIGS. 1A and 1B may be implemented within a single component, or a single component shown in FIGS. 1A and 1B may be implemented as multiple, distributed components. Additionally, or alternatively, a set of components (e.g., one or more components) shown in FIGS. 1A and 1B may perform one or more functions described as being performed by another set of components shown in FIGS. 1A and 1B.

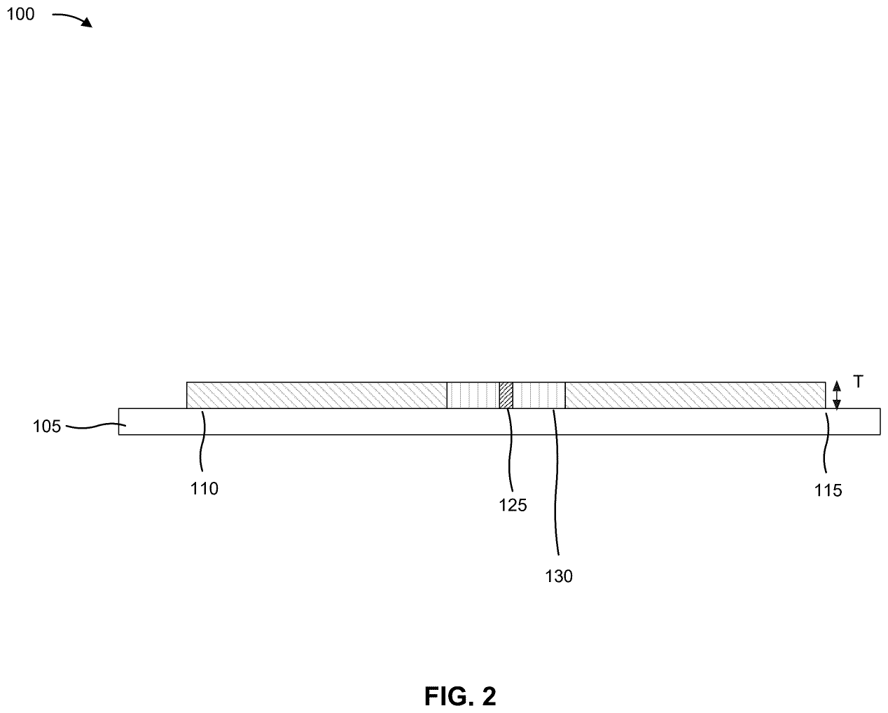

FIG. 2 is a diagram of a cross sectional view along line AA of an example structure 100 described herein. As shown FIG. 2, structure 100 may include a planar solder joint. For example, a thickness T of solder joint 130 may not satisfy a thickness threshold. For instance, the thickness T of solder joint 130 may be 0.030 mm. Similarly, a thickness of first conductive trace 110, second conductive trace 115, and/or PCB 105 may be 0.030 mm. Structure 100, with third conductive trace 125 embedded in the solder, may be ground and polished.

As indicated above, FIG. 2 are provided as examples. Other examples may differ from what is described with regard to FIG. 2.

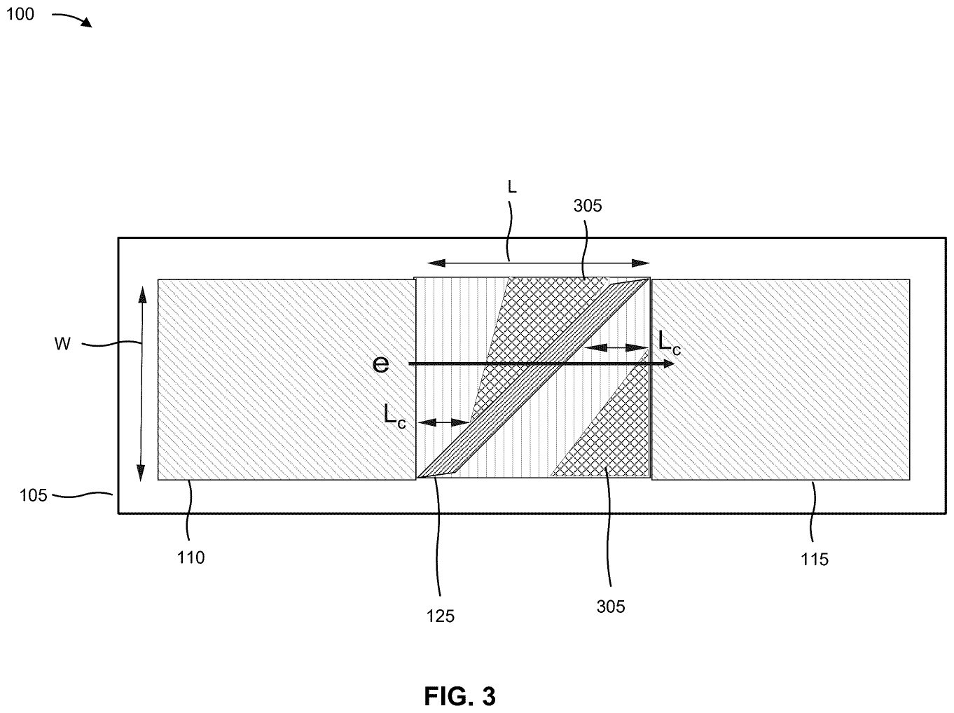

FIG. 3 is a diagram of an electromigration perceived from a top view of an example structure 100 described herein. As shown in FIG. 3, an electron current e of interest at a temperature of interest may be flowed through structure 100 along a length of structure 100. The electron current e may be flowed in this manner for long enough time to start observing a segregation of bismuth atoms 305, as shown in FIG. 3. For example, the electron current e may flow and, as a result, cause an electromigration of bismuth atoms 305 to an anode of structure 100. The electron current e may flow from a cathode of PCB 105 to an anode of PCB 105.

As shown in FIG. 3, bismuth atoms 305 may be segregated in a tapered manner. In this regard, the tapered manner of bismuth atoms 305 (e.g., segregated bismuth atoms) may be due to electromigration back stress. As shown in FIG. 3, third conductive trace 125 may bisect solder joint 130 in a manner that tapers solder joint 130 from the length L to zero. As the length L tapers to a particular solder length L_{c} (a length below which the solder will not electromigrate), the electromigration of bismuth atoms 305 may be reduced to zero.

As shown in FIG. 3, third conductive trace 125 may create a particular solder length L_{c} where a thickness of bismuth atoms 305 is zero. In other words, particular solder length L_{c} may be a length (of solder joint 130) below which solder joint 130 will not be subjected to electromigration of bismuth atoms 305. Accordingly, as shown in FIG. 3, electromigration is a function of the length of solder joint 130. Third conductive trace 125 may change a length of solder joint 130 while maintaining an electron current flowing through solder joint 130.

By changing the length of solder joint 130, third conductive trace 125 may be used to identify a condition under which bismuth atoms 305 will not migrate toward an anode. The novelty of structure 100 is that structure 100 allows uniform current density across the two tapered solder joints in series.

Accordingly, structure that can visually observe the progress of electromigration as a function of length of solder joint 130. Visual observation of the solder structure stressed at high current, and temperature shows the particular solder joint length below which electromigration cannot occur.

To improve the current density uniformity, the diagonal copper trace can be replaced with a less conductive but solderable material. The diagonal copper trace can be made narrower. As shown in FIG. 3, a bismuth accumulation (of bismuth atoms 305) in the solder joint portions may be a triangular shape. For example, the bismuth accumulation may be thicker at one end and tapering to zero. The point where the bismuth accumulation tapers to zero is useful for preventing electromigration of bismuth atoms 305. The length of the solder portion at that point is the particular solder length (L_{c}) of the solder below which electromigration will not occur. In this regard, implementations described herein are to determine the particular solder length of the solder joint below which electromigration will not occur.

As indicated above, FIG. 3 is provided as an example. Other examples may differ from what is described with regard to FIG. 3. The number and arrangement of components shown in FIG. 3 are provided as an example.

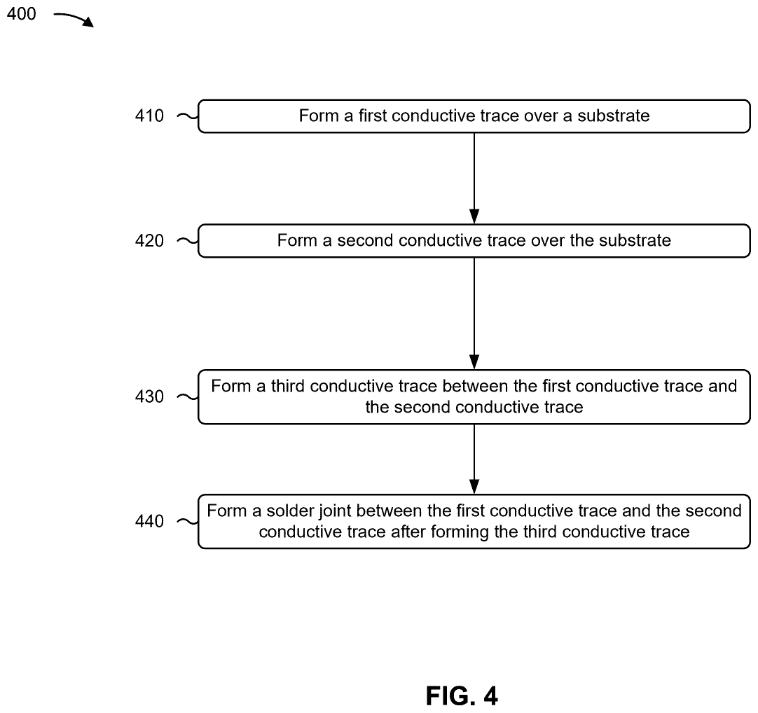

FIG. 4 is a flowchart of an example process 400 associated with solder joint with diagonal trace brief description of the drawings.

As shown in FIG. 4, process 400 may include forming a first conductive trace over a substrate (block 410). For example, the device may form a first conductive trace over a substrate, as described above.

As further shown in FIG. 4, process 400 may include forming a second conductive trace over the substrate, wherein the first conductive trace and the second conductive trace are separated by a length (block 420). For example, the device may form a second conductive trace over the substrate, wherein the first conductive trace and the second conductive trace are separated by a length, as described above. In some implementations, the first conductive trace and the second conductive trace are separated by a length and a first width of the first conductive trace is equal to a second width of the second conductive trace. In some examples, a first length of the first conductive trace is equal to a second length of the second conductive trace.

As further shown in FIG. 4, process 400 may include forming a third conductive trace between the first conductive trace and the second conductive trace (block 430). For example, the device may form a third conductive trace between the first conductive trace and the second conductive trace, as described above. In some implementations, the third conductive trace is provided diagonally between the first conductive trace and the second conductive trace. In some examples, actions of the above blocks (e.g., block 410, block 420, and/or block 430) may be performed simultaneously. In some examples, actions of the above blocks (e.g., block 410, block 420, and/or block 430) may be performed serially (e.g., in sequence).

As further shown in FIG. 4, process 400 may include forming a solder joint between the first conductive trace and the second conductive trace (block 440). For example, the device may form a solder joint between the first conductive trace and the second conductive trace, as described above. In some implementations, the third conductive trace bisects the solder joint diagonally to form a first solder joint portion and a second solder joint portion.

In some implementations, the first width and the second width exceed a width of the third conductive trace.

In some implementations, a first length of the first solder joint portion tapers to zero from the length, and wherein a second length of the second solder joint portion tapers to zero from the length.

In some implementations, the solder joint comprises tin and bismuth, wherein a first length, of the first solder joint portion, tapers to a particular solder length that prevents electromigration of bismuth towards an anode of the substrate, and wherein a second length, of the second solder joint portion, tapers to the particular solder length that prevents electromigration of bismuth towards the anode of the substrate.

In some implementations, forming a solder joint between the first conductive trace and the second conductive trace comprises forming the solder joint after forming the third conductive trace.

In some implementations, the first conductive trace and the second conductive trace comprise copper, and wherein the third conductive trace comprises copper.

In some implementations, the first conductive trace and the second conductive trace comprise copper, wherein the third conductive trace comprises a conductive metal different than copper, and wherein an electrical conductivity of the first conductive trace exceeds an electrical conductivity of the conductive material.

In some implementations, forming the first conductive trace comprise depositing copper on the substrate using electroplating, and wherein forming the third conductive trace comprise forming the third conductive trace using electroplating, wherein the third conductive trace comprises an electroplated wire.

Although FIG. 4 shows example blocks of process 400, in some implementations, process 400 may include additional blocks, fewer blocks, different blocks, or differently arranged blocks than those depicted in FIG. 4. Additionally, or alternatively, two or more of the blocks of process 400 may be performed in parallel.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

As used herein, the term “component” is intended to be broadly construed as hardware, firmware, or a combination of hardware and software. It will be apparent that systems and/or methods described herein may be implemented in different forms of hardware, firmware, and/or a combination of hardware and software. The actual specialized control hardware or software code used to implement these systems and/or methods is not limiting of the implementations. Thus, the operation and behavior of the systems and/or methods are described herein without reference to specific software code—it being understood that software and hardware can be used to implement the systems and/or methods based on the description herein.

As used herein, satisfying a threshold may, depending on the context, refer to a value being greater than the threshold, greater than or equal to the threshold, less than the threshold, less than or equal to the threshold, equal to the threshold, not equal to the threshold, or the like.

Although particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”).

What is claimed is:

1. A method, comprising:
forming a first conductive trace over a substrate;
forming a second conductive trace over the substrate,
wherein the first conductive trace and the second conductive trace are separated by a length, and
wherein a first width of the first conductive trace is equal to a second width of the second conductive trace;
forming a third conductive trace between the first conductive trace and the second conductive trace,
wherein the third conductive trace is provided diagonally between the first conductive trace and the second conductive trace; and
forming a solder joint between the first conductive trace and the second conductive trace, wherein the third conductive trace bisects the solder joint diagonally to form a first solder joint portion and a second solder joint portion.

2. The method of claim 1, wherein a first length of the first solder joint portion tapers to zero from the length, and
wherein a second length of the second solder joint portion tapers to zero from the length.

3. The method of claim 1, wherein a first length of the first solder joint portion tapers from the length to a particular length that prevent electromigration of bismuth in the first solder joint portion, and
wherein a second length of the second solder joint portion tapers from the length to the particular length.

4. The method of claim 1, wherein the solder joint comprises tin and bismuth,
wherein a first length, of the first solder joint portion, tapers to a particular solder length that prevents electromigration of bismuth toward an anode of the substrate,
wherein a second length, of the second solder joint portion, tapers to the particular solder length that prevents electromigration of bismuth toward the anode of the substrate,
wherein the third conductive trace changes a length of the solder, and
wherein, by changing the length of the solder joint, the third conductive trace is used to identify a length that prevent migration of bismuth toward the anode.

5. The method of claim 1, wherein forming a solder joint between the first conductive trace and the second conductive trace comprises:
forming the solder joint after forming the third conductive trace.

6. The method of claim 5, wherein the first conductive trace and the second conductive trace comprise copper, and
wherein the third conductive trace comprises copper.

7. The method of claim 5, wherein the first conductive trace and the second conductive trace comprise copper, and
wherein the third conductive trace comprises a conductive metal different than copper.

8. The method of claim 1, wherein forming the first conductive trace and forming the second conductive comprise:
depositing copper on the substrate using electroplating, and
wherein forming the third conductive trace comprise:
forming the third conductive trace using electroplating,
wherein the third conductive trace comprises an electroplated wire.

9. A substrate comprising:
a first conductive trace over a substrate;
a second conductive trace over the substrate,
wherein the first conductive trace and the second conductive trace are separated by a length;
a solder joint bridging the first conductive trace and the second conductive trace; and
a third conductive trace diagonally bisecting the solder joint to form a first solder joint portion and a second solder joint portion,
wherein a first length of the first solder joint portion tapers to zero from the length, and
wherein a second length of the second solder joint portion tapers to zero from the length.

10. The substrate of claim 9, wherein a first thickness of the first conductive trace is equal to a second thickness of the second conductive trace.

11. The substrate of claim 9, wherein a first width of the first conductive trace is equal to a second width of the second conductive trace.

12. The substrate of claim 9, wherein a first length of the first solder joint portion tapers from the length to a particular length that prevent electromigration of bismuth in the first solder joint portion, and
wherein a second length of the second solder joint portion tapers from the length to the particular length.

13. The substrate of claim 9, wherein the solder joint comprises tin and bismuth,
wherein a first length, of the first solder joint portion, tapers to a particular solder length that prevents electromigration of bismuth toward an anode of the substrate, and
wherein a second length, of the second solder joint portion, tapers to the particular solder length that prevents electromigration of bismuth toward the anode of the substrate.

14. The substrate of claim 9, wherein the first conductive trace and the second conductive trace comprise copper, and
wherein the solder joint comprises tin and bismuth.

15. The substrate of claim 14, wherein the third conductive trace comprises copper.

16. The substrate of claim 14, wherein the third conductive trace comprises nickel titanium alloy.

17. The substrate of claim 14, wherein the third conductive trace comprises nichrome.

18. A substrate comprising:
a first conductive trace over a substrate;
a second conductive trace over the substrate;
a planar, thin, rectangular solder joint bridging a first conductive trace and a second conductive trace that are of a same thickness and width; and
a third conductive trace that diagonally bisects the solder joint to provide two solder joint portions, each solder joint point having a length tapering to zero such that each solder joint portion ensures uniform current density.

19. The substrate of claim 18, wherein a first width of the first conductive trace and a second width of the second conductive trace exceed a third width of the third conductive trace.

20. The substrate of claim 18, wherein the solder joint comprises tin and bismuth,
wherein a first length, of a first solder joint portion of the two solder joint portions, tapers to a particular solder length that prevents electromigration of bismuth toward an anode of the substrate, and
wherein a second length, of a second solder joint portion of the two solder joint portions, tapers to the particular solder length that prevents electromigration of bismuth toward the anode of the substrate.
